(19) United States
(12) Patent Application Publication
(10) Pub. No.: US 2014/0366946 A1
(43) Pub. Date: Dec. 18, 2014

(54) Multi-layer compound precursor with CuSe thermal conversion to Cu2-xSe for two-stage CIGS solar cell absorber synthesis

(71) Applicant: HelioVolt Corporation, Austin, TX (US)

(72) Inventors: Baosheng Sang, Austin, TX (US); Dingyuan Lu, Austin, TX (US); Roy M. Miller, Austin, TX (US); Casiano R. Martinez, Dale, TX (US); Billy J. Stanbery, Austin, TX (US)

(21) Appl. No.: 13/919,100

(22) Filed: Jun. 17, 2013

(51) Int. Cl. H01L 31/0336; H01L 31/18

(52) U.S. Cl. CPC H01L 31/0336; H01L 31/18
USPC 136/262; 438/94

(57) ABSTRACT

Fabricating a layered precursor includes depositing a first film including a first indium gallium selenide compound on a substrate; then depositing a second film including a first CuSe compound; then heating the substrate, the first film and the second film to convert the first CuSe compound in the second film to a first Cu₂₋ₓSe (0=<x<1) compound; and then depositing a third film including a indium gallium selenide compound. A layered precursor includes a substrate; a first film coupled to the substrate, the first film including a first indium gallium selenide compound; a second film coupled to the first film, the second film including a first Cu₂₋ₓSe where (0=<x<=1) compound; and a third film coupled to the second film, the third film including a second indium gallium selenide compound.

### FIELD OF THE INVENTION

The invention relates generally to the field of precursors for GIGS (copper indium gallium selenide) solar cell absorber synthesis. More particularly, the invention relates to a multi-layer compound precursor having a transitory CuSe compound that is converted to Cu₂₋ₓSe for two-stage CIGS solar cell absorber synthesis.

### BACKGROUND

Among many GIGS fabrication methods, there are two common approaches. The two common approaches include the CIGS direct-synthesis co-evaporation processes and the two-step metal precursor selenization CIGS absorber fabrication methods.

GIGS co-evaporation processes suffer from a difficult to achieve but necessary strict flux control and a high thermal budget. CIGS co-evaporation process depends on the precise control of the fluxes from all the evaporation sources and high substrate temperature to achieve the desired material phase, structural and electronic properties, and composition depth profile. A practical consequence is difficult and expensive scale up for large area GIGS cells and modules.

Two-step metal precursor selenization GIGS absorber fabrication is compatible with standard and well established techniques for metal deposition and reaction and annealing steps. However, this two-step metal precursor selenization CIGS absorber fabrication process has limited ability to control composition profiles and is slow since it is a diffusion-limited process.

### SUMMARY

There is a need for the following embodiments of the present disclosure. Of course, the present disclosure is not limited to these embodiments.

According to an embodiment of the present disclosure, a process comprises: fabricating a layered precursor includes: depositing a first film including a first indium gallium selenide compound on a substrate; then depositing a second film including a first CuSe compound; then heating the substrate, the first film and the second film to convert the first CuSe compound in the second film to a first Cu₂₋ₓSe (0=<x<1) compound; and then depositing a third film including a indium gallium selenide compound. According to another embodiment of the present disclosure, a composition of matter comprises: a layered precursor including a substrate; a first film coupled to the substrate, the first film including a first indium gallium selenide compound; a second film coupled to the first film, the second film including a first Cu₂₋ₓSe where (0=<x<=1) compound; and a third film coupled to the second film, the third film including a second indium gallium selenide compound.

These, and other, embodiments of the present disclosure will be better appreciated and understood when considered in conjunction with the following description and the accompanying drawings. It should be understood, however, that the following description, while indicating various embodiments of the present disclosure and numerous specific details thereof, is given for the purpose of illustration and does not imply limitation. Many substitutions, modifications, additions and/or rearrangements may be made within the scope of embodiments of the present disclosure, and embodiments of the present disclosure include all such substitutions, modifications, additions and/or rearrangements.

### BRIEF DESCRIPTION OF THE DRAWINGS

The drawings accompanying and forming part of this specification are included to depict certain embodiments of the present disclosure. A clearer concept of the embodiments described in this application will be readily apparent by referring to the exemplary, and therefore nonlimiting, embodiments illustrated in the drawings (wherein identical reference numerals (if they occur in more than one view) designate the same elements). The described embodiments may be better understood by reference to one or more of these drawings in combination with the following description presented herein. It should be noted that the features illustrated in the drawings are not necessarily drawn to scale.

FIG. 1 illustrates X-Ray Diffraction (XRD) patterns showing an example of the thermal conversion process from CuSe to Cu₂₋ₓSe.

FIG. 2 illustrates a process flow schematic showing fabrication of a three-layer precursor plus a Se cap film.

FIG. 3 illustrates a process flow schematic showing fabrication of a five-layer precursor plus a Se cap film.

### DETAILED DESCRIPTION

Embodiments presented in the present disclosure and the various features and advantageous details thereof are explained more fully with reference to the nonlimiting embodiments that are illustrated in the accompanying drawings and detailed in the following description. Descriptions of well known starting materials, processing techniques, components and equipment are omitted so as not to unnecessarily obscure the embodiments of the present disclosure in detail. It should be understood, however, that the detailed description and the specific examples are given by way of illustration only and not by way of limitation. Various substitutions, modifications, additions and/or rearrangements within the scope of the underlying inventive concept will become apparent to those skilled in the art from this disclosure.

The inclusion of the thermal conversion of CuSe to Cu₂₋ₓSe (0=<x=<1.0), preferably (0=<x=<0.4), (e.g. x=0.2) in a multi-layer compound precursor deposition is a way to introduce compositionally uniform and smooth morphology Cu₂₋ₓSe material as a precursor layer while enabling a robust manufacturing process, economical precursor deposition process, and uniform CIGS composition and phase control for large area CIGS absorber synthesis with high device performance. Embodiments of the present disclosure provide commercial advantages because they solve several problems.

A first problem that embodiment of the present disclosure address is difficult, strict flux control and high thermal budget in CIGS direct synthesis co-evaporation processes, and both poor composition depth profile control and slow processing with two-stage metal precursor selenization CIGS absorber fabrication methods. The conventional CIGS co-evaporation process depends on high substrate temperature to achieve desired material phase, structural and electronic property quality. A practical consequence is difficult and expensive scale up for large area CIGS cells and module manufacturing. Two-step metal selenization CIGS absorber fabrication is compatible with standard and well established techniques for metal deposition, selenization reaction and annealing steps. However, this process has limited ability to control composition profiles and is slow because its rate is limited by the diffusion of selenium through the metal precursor film. Embodiments of the present disclosure include a multi-layer compound precursor for two-stage CIGS absorber synthesis that involves the deposition of multiple compound precursor layers at lower temperature, followed by CIGS reaction under Se over pressure (e.g. from a Se layer on the compound precursor layers, or Se vapor source integrated into the precursor reaction tool). This provides the capability of easy composition depth profile and phase control in the CIGS absorber with lower total thermal budget and rapid processing, which is suitable for scaling-up to low cost, large area cell and module manufacturing.

A second problem that embodiments of the present disclosure address is rough Cu₂₋ₓSe surface via direct binary compound film formation from elemental sources at elevated temperatures. CuSe deposition at low temperature creates a much smoother surface morphology than direct deposition of Cu₂₋ₓSe layers. When converted into Cu₂₋ₓSe this smoother surface morphology is retained in the final film, which improves uniform film coverage of subsequent layers, and the compositional uniformity of their reaction products.

A third problem that embodiments of the present disclosure address is compositional nonuniformity. The process window in terms of flux ratios and temperatures required to form compositionally uniform value of x in Cu₂₋ₓSe layers is narrow for the direct growth of Cu₂₋ₓSe from elemental sources. Embodiments of the present disclosure enable an easy-to-control two-stage process to obtain compositionally uniform (uniform value of x) Cu₂₋ₓSe material at lower temperatures. CuSe with uniform composition is deposited first at lower temperature, which provides a larger process window including both i) the Se to metal ratio and ii) the process temperatures. Then CuSe material can be converted to a compositionally and structurally uniform Cu₂₋ₓSe layer when heated to higher temperature.

The process can be implemented with a multi-chamber sequential processing apparatus. The multi-chamber sequential processing apparatus can include evaporation deposition chambers with heating for material deposition at the desired process temperatures. The multi-chamber sequential processing apparatus can also include additional heating/cooling chambers in between the deposition chambers to modulate for proper process temperatures. The three evaporation chambers are used for the 3-layer precursor material deposition include chambers for the 1) initial (In_{1-y}Ga_{y})₂Se₃ thin film layer, 2) the CuSe thin film layer and 3) the (final) (In_{1-y}Ga_{y})₂Se₃ thin film layer.

The process can be implemented with a multi-chamber sequential deposition chamber apparatus. The multi-chamber sequential processing apparatus can include evaporation deposition chambers with heating for material deposition at the desired process temperatures. The multi-chamber sequential processing apparatus can also include additional heating/cooling chambers in between the deposition chambers to modulate for proper process temperatures. The three evaporation chambers are used for the 3-layer precursor material deposition can include chambers for the 1) initial (In_{1-y}Ga_{y})₂Se₃ thin film layer, where 0≦y≦1, 2) the CuSe thin film layer and 3) the final (In_{1-z}Ga_{z})₂Se₃ thin film layer, where 0≦z≦1. During the panel processing, the molybdenum-coated soda lime glass substrates first enter the heating chambers and are heated to a substrate temperature lower than approximately 400° C. under vacuum for the substrates to receive the deposition of a first layer with composition (In_{y}Ga_{1-y})₂Se₃ in the first evaporation chamber, where 0≦y≦1, and preferably 0.2≦y≦0.5. Then the substrates continue (are moved) to the cooling chamber(s) for a target substrate temperature of below approximately 275° C., preferably equal to or below approximately 200° C., where CuSe deposition is conducted. Then, the substrates are heated to a substrate temperature higher than approximately 275° C. for conversion of CuSe to Cu₂₋ₓSe (0≦x≦1), followed by a layer deposition of an (In_{1-y2}Ga_{y2})₂Se₃ compound at a substrate temperature lower than approximately 400° C., where 0≦y2≦1, and preferably 0.2≦y2≦0.5. The finished multi-layer precursor then receives a thin selenium cap layer at approximately room temperature prior to annealing this precursor structure at elevated temperature in a selenium vapor in a reaction tool to form CIGS.

For instance, during the panel processing, the molybdenum-coated soda lime glass substrates first enter the heating chambers and are heated to a temperature lower than approximately 380° C. substrate temperature under vacuum to prepare the substrates for the deposition of a first layer with composition (In_{0.8-0.5}Ga_{0.2-0.5})₂Se₃. Then the substrates continue (are moved) to the cooling chambers for a target substrate temperature of below approximately 275° C., where CuSe deposition is conducted. Then, the substrates are heated to a substrate temperature lower than approximately 400° C. for conversion of CuSe to Cu₂₋ₓSe, followed by the (final) layer deposition of an (In_{0.8-0.5}Ga_{0.2-0.5})₂Se₃ compound. The finished multi-layer precursor then receives a thin selenium (optionally with S and/or Na) cap layer at room temperature prior to annealing this precursor structure at elevated temperature in a selenium vapor in a reaction tool to form CIGS.

A five- or more-layer precursor deposition, as opposed to a three-layer precursor deposition, can provide more benefits of material gradient flexibility and possibly more controls over the material properties and morphology. This could also be combined with a cluster tool to offer manufacturing flexibility simultaneously.

Other material deposition methods, as opposed to the thermal evaporation under vacuum, such as compound-target or reactive sputtering, liquid precursor, or other hybrid deposition methods, can also be utilized for the fabrication of the multi-layer compound precursor with Cu—Se thermal conversion to Cu₂₋ₓSe for the two-stage GIGS solar cell absorber synthesis. These alternatives can possible enable a lower manufacturing cost structure, or better precursor or final CIGS film properties for better device performances.

### EXAMPLES

Specific exemplary embodiments will now be further described by the following, nonlimiting examples which will serve to illustrate in some detail various features. The following examples are included to facilitate an understanding of ways in which embodiments of the present disclosure may be practiced. However, it should be appreciated that many changes can be made in the exemplary embodiments which are disclosed while still obtaining like or similar result without departing from the scope of embodiments of the present disclosure. Accordingly, the examples should not be construed as limiting the scope of the present disclosure.

### Example 1

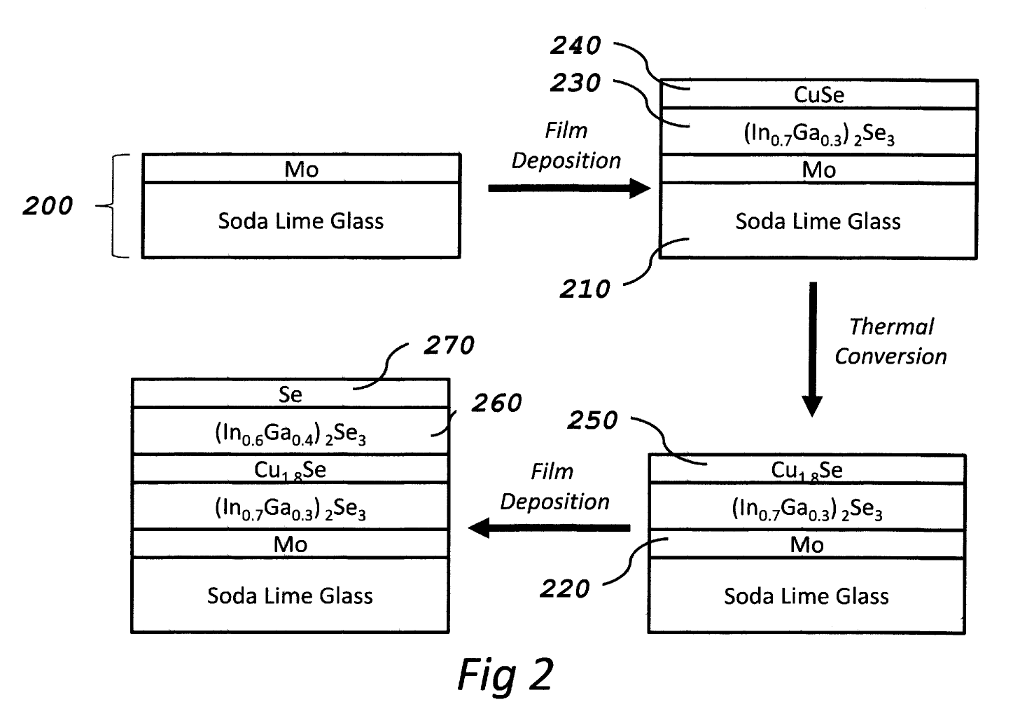

Referring to FIG. 2, a substrate 200 includes soda lime glass 210 coated with a conductive layer of molybdenum (Mo) 220. A layer of indium gallium selenide 230 is deposited at a temperature lower than 400° C. A CuSe layer 240 deposition follows at a temperature below 275° C. and preferably below 200° C. CuSe film deposition is done without the need for precise control or uniformity of the Se to metal flux ratio, and the ratio of indium gallium selenide to CuSe film thicknesses can be adjusted to achieve the desired final material composition depth profile. The stacked layers are then heated to a temperature above 275° C. to convert the surface CuSe material into compositionally uniform Cu₂₋ₓSe material, in this example Cu_{1.8}Se material 250.

In this example, the above steps are performed once, but the above steps can be repeated (optionally multiple times) to fabricate multiple precursor layer pairs. The deposition of a single-layer precursor pair can be finished with the deposition of a layer of indium gallium selenide 260. The process also includes deposition of thin film cap layer 270 including elemental selenium optionally with sulfur and/or sodium (mixture(s)).

The multi-layer compound precursor can be reacted at elevated temperature under Se or Se+S overpressure. Examples of Se or Se+S supply during reaction include the thin film cap layer on top of multi-layer precursor and/or independently controlled Se and optionally S vapor sources directly integrated to a CIGS reaction tool.

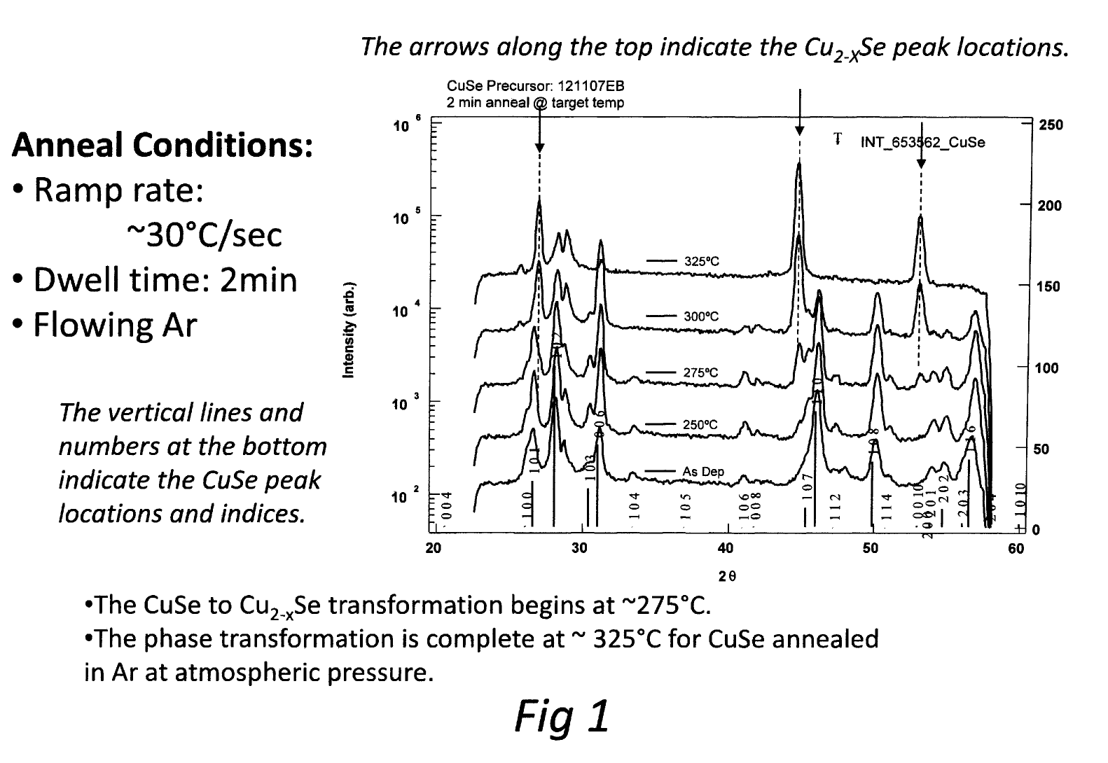

A multi-layer compound precursor with CuSe thermal conversion to Cu₂₋ₓSe using 2-step CIGS solar cell absorber synthesis and 14-15% 600×1200 mm module efficiency has been demonstrated in a production line. The conversion of CuSe to Cu₂₋ₓSe is documented in FIG. 1.

### Example 2

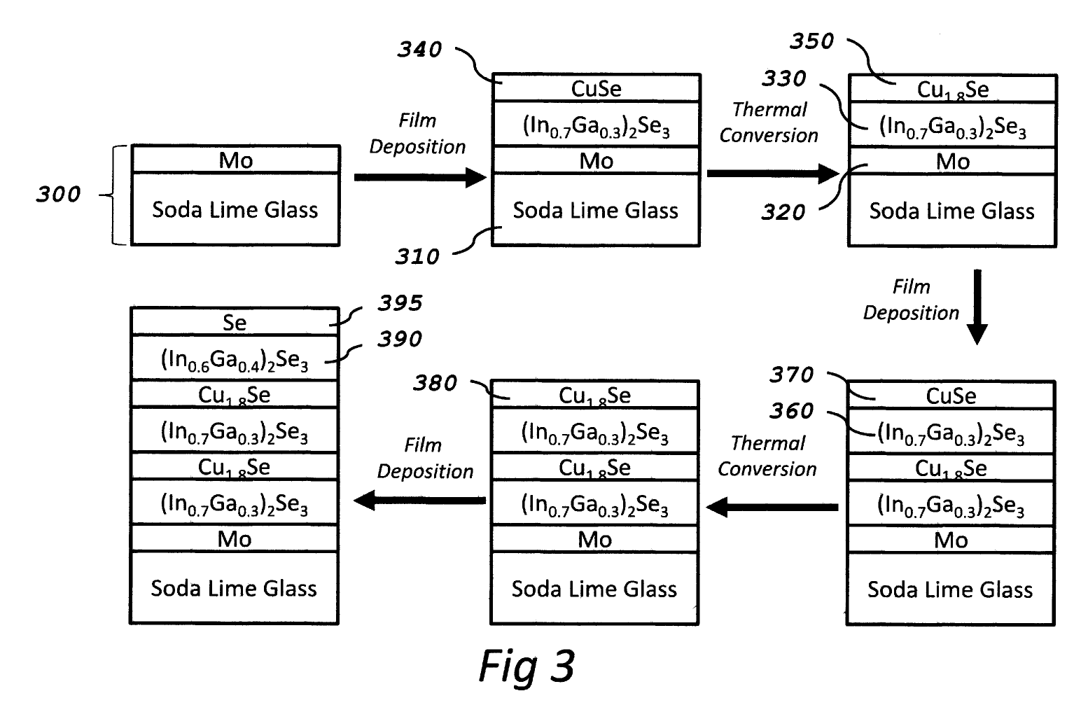

Referring to FIG. 3, a substrate 300 includes soda lime glass 310 coated with a back contact film of Mo 320. A layer of indium gallium selenide 330 is deposited at a temperature lower than 400° C. A CuSe layer 340 deposition follows at a temperature below 275° C. and preferably below 200° C. Again, CuSe film deposition is done without the need for precise control or uniformity of the Se to metal flux ratio since excess Se re-evaporates from the surface in this temperature range, and the ratio of indium gallium selenide to CuSe film thicknesses can be adjusted to achieve the desired final material composition depth profile. The stacked layers are then heated to a temperature above 275° C. to convert the surface CuSe material into compositionally uniform Cu₂₋ₓSe material, in this example uniform Cu_{1.8}Se material 350.

In this example, the above steps are repeated once (optionally multiple times) to fabricate multiple precursor layer pairs. This includes deposition of a layer of indium gallium selenide 360 and another CuSe layer 370 deposition follows at a temperature below 275° C. and preferably below 200° C. Again, the CuSe film deposition is done without the need for precise control or uniformity of the Se to metal flux ratio, and the ratio of indium gallium selenide to CuSe film thicknesses can be adjusted to achieve the desired final material composition depth profile. The stacked layers are then heated to a temperature above 275° C. to convert the surface CuSe material into compositionally uniform Cu₂₋ₓSe material, in this example uniform Cu_{1.8}Se material 380. The deposition of multi-layer precursor pairs can be finished with the deposition of a layer of indium gallium selenide 390. Optionally, the process can also include deposition of thin film cap layer 395 including elemental selenium, optionally with sulfur and/or sodium (mixture(s)).

Again, the multi-layer compound precursor can be reacted at elevated temperature under Se or Se+S overpressure. Again, examples of Se or Se+S supply during reaction include the thin film cap layer on top of multi-layer precursor and/or independently controlled Se and optionally S vapor sources directly integrated to a CIGS reaction tool.

### Advantages

Embodiments of the present disclosure can be cost effective and advantageous for at least the following reasons. Preferred embodiments of the present disclosure can provide more than one (or all) of the following advantages simultaneously.

First, using a multi-layer compound precursor for two-stage CIGS synthesis provides flexible manufacturing and easy to reproduce material composition uniformity, variable-composition depth profile, and thermodynamic phase control of precursors and the final GIGS film, enabling scaling-up capability for large area cell and module manufacturing and better device performance. The formation of the CuSe compound at lower temperatures than those temperatures at which the Cu₂₋ₓSe can be deposited increases the accommodation coefficient for selenium, reducing the selenium re-evaporation rate and increasing the selenium utilization efficiency, while reducing the rate of selenium waste buildup on deposition chamber walls.

Second, the inclusion of Cu₂₋ₓSe into the precursor structure via thermal conversion from CuSe grown at lower temperature has solved several technical issues including surface roughness, material compositional and structural uniformity, and void formation and/or layer delamination in the film during the two-stage process if an additional (for example indium gallium selenide) material is deposited on top of a substantially unconverted CuSe layer. These improvements result in better device performance.

Third, separation of precursor fabrication and GIGS reaction provides flexibility in reaction pathway control for device performance improvement. This is an important research and development advantage.

Fourth, total thermal budget with the two-stage CIGS synthesis method can be lower compared to both co-evaporation and two-step metal-selenization GIGS fabrication. This is an important energy saving and economic advantage.

Fifth, processing time with the two-stage CIGS synthesis method can be lower compared to both co-evaporation and two-step metal-selenization CIGS fabrication. This is an important time saving and economic advantage. Thus, embodiments of the present disclosure improve quality and reduce costs compared to previous approaches.

### DEFINITIONS

The term compound is intended to mean a substance formed when two or more chemical elements are chemically bonded together, the elements present in ratios with a limited range of variation and characteristic crystal structure. The term phase is intended to mean a limited range of compositions of a mixture of the elements (in a thermochemical system) throughout which the chemical potential of the mixture varies with composition, and which either changes discontinuously or remains constant outside of that range. The phrase cation content is intended to mean the percentage or relative amount of a given cation of interest (relative to total cations) in a given volume or mass of interest. The term absorber is intended to mean the photon absorbing portion of a photovoltaic. The term buffer is intended to mean the junction forming region of a photovoltaic. The term emitter is intended to mean the negative contact of an illuminated photovoltaic without current flow. The term amorphous transparent conductive layer is intended to mean a non-crystalline, substantially photon transparent, electronically conducting portion of a photovoltaic. The term back contact is intended to mean the contact of a photovoltaic on the side opposite the incident illumination. The term photovoltaic is intended to mean an article of manufacture for the generation of a voltage when radiant energy falls on the boundary between dissimilar substances (as two different semiconductors). Group numbers corresponding to columns within the periodic table of the elements use the “New Notation” convention as seen in the CRC Handbook of Chemistry and Physics, 93^{st} Edition (2012).

The term substantially is intended to mean largely but not necessarily wholly that which is specified. The term approximately is intended to mean at least close to a given value (e.g., within 10% of). The term generally is intended to mean at least approaching a given state. The term coupled is intended to mean connected, although not necessarily directly, and not necessarily mechanically. The term deploying is intended to mean designing, building, shipping, installing and/or operating.

The terms first or one, and the phrases at least a first or at least one, are intended to mean the singular or the plural unless it is clear from the intrinsic text of this document that it is meant otherwise. The terms second or another, and the phrases at least a second or at least another, are intended to mean the singular or the plural unless it is clear from the intrinsic text of this document that it is meant otherwise. Unless expressly stated to the contrary in the intrinsic text of this document, the term or is intended to mean an inclusive or and not an exclusive or. Specifically, a condition A or B is satisfied by any one of the following: A is true (or present) and B is false (or not present), A is false (or not present) and B is true (or present), and both A and B are true (or present). The terms a and/or an are employed for grammatical style and merely for convenience.

The term plurality is intended to mean two or more than two. The term any is intended to mean all applicable members of a set or at least a subset of all applicable members of the set. The term means, when followed by the term “for” is intended to mean hardware, firmware and/or software for achieving a result. The term step, when followed by the term “for” is intended to mean a (sub)method, (sub)process and/or (sub)routine for achieving the recited result. Unless otherwise defined, all technical and scientific terms used herein have the same meaning as commonly understood by one of ordinary skill in the art to which this present disclosure belongs. In case of conflict, the present specification, including definitions, will control.

The described embodiments and examples are illustrative only and not intended to be limiting. Although embodiments of the present disclosure can be implemented separately, embodiments of the present disclosure may be integrated into the system(s) with which they are associated. All the embodiments of the present disclosure disclosed herein can be made and used without undue experimentation in light of the disclosure. Embodiments of the present disclosure are not limited by theoretical statements (if any) recited herein. The individual steps of embodiments of the present disclosure need not be performed in the disclosed manner, or combined in the disclosed sequences, but may be performed in any and all manner and/or combined in any and all sequences. The individual components of embodiments of the present disclosure need not be formed in the disclosed shapes, or combined in the disclosed configurations, but could be provided in any and all shapes, and/or combined in any and all configurations. The individual components need not be fabricated from the disclosed materials, but could be fabricated from any and all suitable materials. Homologous replacements may be substituted for the substances described herein.

Various substitutions, modifications, additions and/or rearrangements of the features of embodiments of the present disclosure may be made without deviating from the scope of the underlying inventive concept. All the disclosed elements and features of each disclosed embodiment can be combined with, or substituted for, the disclosed elements and features of every other disclosed embodiment except where such elements or features are mutually exclusive. The scope of the underlying inventive concept as defined by the appended claims and their equivalents cover all such substitutions, modifications, additions and/or rearrangements.

The appended claims are not to be interpreted as including means-plus-function limitations, unless such a limitation is explicitly recited in a given claim using the phrase(s) “means for” “mechanism for” and/or “step for”. Subgeneric embodiments of the invention are delineated by the appended independent claims and their equivalents. Specific embodiments of the invention are differentiated by the appended dependent claims and their equivalents.

What is claimed is:

1. A method, comprising fabricating a layered precursor including:
depositing a first film including a first indium gallium selenide compound on a substrate; then
depositing a second film including a first CuSe compound; then
heating the substrate, the first film and the second film to convert the first CuSe compound in the second film to a first Cu₂₋ₓSe (0=<x<1) compound; and then
depositing a third film including a indium gallium selenide compound.

2. The method of claim 1, wherein
depositing the first film includes depositing a (In_{1-y}Ga_{y})₂Se₃ (0=<y<=1) compound on the substrate;
and
depositing the third film includes depositing a (In_{1-y2}Ga_{y2})₂Se₃ (0=<y2<=1) compound.

3. The method of claim 2, wherein the first film includes an approximately (In_{0.8-0.5}Ga_{0.2-0.5})₂Se₃ compound.

4. The method of claim 1, wherein after heating the second film includes an approximately Cu_{1.8}Se compound.

5. The method of claim 2, wherein the third film includes an approximately (In_{0.8-0.5}Ga_{0.2-0.5})₂Se₃ compound.

6. The method of claim 2, further comprising depositing a cap film includes Se.

7. The method of claim 6, wherein the cap film includes Se₁₋ₛSₛ with optional Na, where 0≦s≦1.

8. The method of claim 2, further comprising
depositing a fourth film including a second CuSe compound; then
heating the substrate, the first film, the second film, the third film and the fourth film to convert the second CuSe compound in the fourth film to a second Cu₂₋ₓ₂Se (0=<x2<=1) compound; and then
depositing a fifth film including a third (In_{1-y3}Ga_{y3})₂Se₃ (0=<y3<=1) compound.

9. The method of claim 8, further comprising depositing a cap film including Se.

10. The method of claim 9, wherein the cap film includes Se₁₋ₛSₛ with optional Na, where 0≦s≦1.

11. The method of claim 8, further comprising
depositing a sixth film including a third CuSe compound; then
heating the substrate, the first film, the second film, the third film, the fourth film, the fifth film and the sixth film to convert the third CuSe compound in the sixth film to a third Cu₂₋ₓ₃Se (0=<x3<=1) compound; and then
depositing a seventh film including a fourth (In_{1-y4}Ga_{y4})₂Se₃ (0=<y4<=1) compound.

12. The method of claim 1, further comprising annealing the first film, the second film and the third film in a selenium vapor atmosphere to form a copper, indium, gallium, selenide film.

13. A composition, comprising a layered precursor including:
a substrate;
a first film coupled to the substrate, the first film including a first indium gallium selenide compound;
a second film coupled to the first film, the second film including a first Cu₂₋ₓSe where (0=<x<=1) compound; and
a third film coupled to the second film, the third film including a second indium gallium selenide compound.

14. The composition of claim 13, wherein the first indium gallium selenide compound includes a first (In_{1-y}Ga_{y})₂Se₃ (0=<y<=1) compound.

15. The composition of claim 14, wherein (0.2=<y<=0.5).

16. The composition of claim 13, wherein (0.2=<x<=0.4).

17. The composition of claim 13, wherein the second indium gallium selenide compound includes a second (In_{1-y2}Ga_{y2})₂Se₃ compound where (0.2=<y2<=0.5).

18. The composition of claim 13, further comprising a cap film coupled to the third film, the cap film including Se.

19. The composition of claim 18, wherein the cap film includes Se₁₋ₛSₛ with optional Na, where 0≦s≦1.

20. The composition of claim 13, further comprising
a fourth film coupled to the third film, the fourth film including one member selected from the group consisting of a second CuSe compound or a second Cu₂₋ₓ₂Se where (0=<x2<=1) compound.

21. The composition of claim 20, wherein (0.2=<x2<=0.4).

22. The composition of claim 20, wherein the fourth film includes the second Cu₂₋ₓ₂Se (0=<x2<=1) compound, and, further comprising
a fifth film coupled to the fourth film, the fifth film including a third (In_{1-y3}Ga_{y3})₂Se₃ (0=<y3<=1) compound.

23. The composition of claim 22, wherein (0.2=<y3<=0.5).

24. The composition of claim 23, further comprising a cap film coupled to the fifth film, the cap film includes Se.

25. The composition of claim 24, wherein the cap film includes Se₁₋ₛSₛ with optional Na, where 0≦s≦1.
